(19) United States
(12) Patent Application Publication
(10) Pub. No.: US 2019/0056665 A1
(43) Pub. Date: Feb. 21, 2019

(54) PHOTO-IMAGEABLE THIN FILMS WITH HIGH DIELECTRIC CONSTANTS

(71) Applicant: Dow Global Technologies LLC, Midland, MI (US)

(72) Inventors: Caroline Woelfle-Gupta, Midland, MI (US); Yuanqiao Rao, Freeport, TX (US); William H.H. Woodward, Midland, MI (US)

(21) Appl. No.: 16/079,349

(22) PCT Filed: Mar. 15, 2017
(86) PCT No.: PCT/US2017/022397

§ 371 Date: Aug. 23, 2018

Related U.S. Application Data
(60) Provisional application No. 62/312,626, filed on Mar. 24, 2016.

(51) Int. Cl. G03F 7/038; G03F 7/023; G03F 7/004; C01G 25/02

(52) U.S. Cl. CPC G03F 7/0385; G03F 7/0236; C08K 2003/2244; C01G 25/02; G03F 7/0045

(57) ABSTRACT

A formulation for preparing a photo-imageable film; said formulation comprising: (a) a positive photoresist comprising a cresol novolac resin and a diazonaphthoquinone inhibitor; and (b) functionalized zirconium oxide nanoparticles.

### FIELD OF THE INVENTION

The present invention relates to a photo-imageable thin film with a high dielectric constant.

### BACKGROUND OF THE INVENTION

High dielectric constant thin films are of high interest for applications such as embedded capacitors, TFT passivation layers and gate dielectrics, in order to further miniaturize microelectronic components. One approach for obtaining a photo-imageable high dielectric constant thin film is to incorporate high dielectric constant nanoparticles in a photoresist. U.S. Pat. No. 7,630,043 discloses composite thin films based on a positive photoresist containing an acrylic polymer having alkali soluble units such as a carboxylic acid, and fine particles having a dielectric constant higher than 4. However, this reference does not disclose the binder used in the present invention.

### SUMMARY OF THE INVENTION

The present invention provides a formulation for preparing a photo-imageable film; said formulation comprising: (a) a positive photoresist comprising a cresol novolac resin and a diazonaphthoquinone inhibitor; and (b) functionalized zirconium oxide nanoparticles.

### DETAILED DESCRIPTION OF THE INVENTION

Percentages are weight percentages (wt %) and temperatures are in ° C., unless specified otherwise. Operations were performed at room temperature (20-25° C.), unless specified otherwise. The term “nanoparticles” refers to particles having a diameter from 1 to 100 nm; i.e., at least 90% of the particles are in the in size range and the maximum peak height of the particle size distribution is within the range. Preferably, nanoparticles have an average diameter 75 nm or less; preferably 50 nm or less; preferably 25 nm or less; preferably 10 nm or less; preferably 7 nm or less. Preferably, the average diameter of the nanoparticles is 0.3 nm or more; preferably 1 nm or more. Particle sizes are determined by Dynamic Light Scattering (DLS). Preferably the breadth of the distribution of diameters of zirconia particles, as characterized by breadth parameter BP=(N75−N25), is 4 nm or less; more preferably 3 nm or less; more preferably 2 nm or less. Preferably the breadth of the distribution of diameters of zirconia particles, as characterized by BP=(N75−N25), is 0.01 or more. It is useful to consider the quotient W as follows:

W=(N75−N25)/Dm

where Dm is the number-average diameter. Preferably W is 1.0 or less; more preferably 0.8 or less; more preferably 0.6 or less; more preferably 0.5 or less; more preferably 0.4 or less. Preferably W is 0.05 or more.

Preferably, the functionalized nanoparticles comprise zirconium oxide and one or more ligands, preferably ligands which have alkyl, heteroalkyl (e.g., poly(ethylene oxide)) or aryl groups having polar functionality; preferably carboxylic acid, alcohol, trichlorosilane, trialkoxysilane or mixed chloro/alkoxy silanes; preferably carboxylic acid. It is believed that the polar functionality bonds to the surface of the nanoparticle. Preferably, ligands have from one to twenty-five non-hydrogen atoms, preferably one to twenty, preferably three to twelve. Preferably, ligands comprise carbon, hydrogen and additional elements selected from the group consisting of oxygen, sulfur, nitrogen and silicon. Preferably alkyl groups are from C₁-C₁₈, preferably C₂-C₁₂, preferably C₃-C₈. Preferably, aryl groups are from C₆-C₁₂. Alkyl or aryl groups may be further functionalized with isocyanate, mercapto, glycidoxy or (meth)acryloyloxy groups. Preferably, alkoxy groups are from C₁-C₄, preferably methyl or ethyl. Among organosilanes, some suitable compounds are alkyltrialkoxysilanes, alkoxy(polyalkyleneoxy)alkyltrialkoxysilanes, substituted-alkyltrialkoxysilanes, phenyltrialkoxysilanes, and mixtures thereof. For example, some suitable organosilanes are n-propyltrimethoxysilane, n-propyltriethoxysilane, n-octyltrimethoxysilane, n-octyltriethoxysilane, phenyltrimethoxysilane, 2-[methoxy(polyethyleneoxy)propyl]-trimethoxysilane, methoxy(triethyleneoxy)propyltrimethoxysilane, 3-aminopropyltrimethoxysilane, 3-mercaptopropyltrimethoxysilane, 3-(methacryloyloxy)propyl trimethoxysilane, 3-isocyanaopropyltriethoxysilane, 3-isocyanatopropyltrimethoxysilane, glycidoxypropyltrimethoxysilane, and mixtures thereof.

Among organoalcohols, preferred are alcohols or mixtures of alcohols of the formula R¹⁰OH, where R¹⁰ is an aliphatic group, an aromatic-substituted alkyl group, an aromatic group, or an alkylalkoxy group. Mote preferred organoalcohols are ethanol, propanol, butanol, hexanol, heptanol, octant dodecyl alcohol, octadecanol, benzyl alcohol, phenol, oleyl alcohol, triethylene glycol monomethyl ether, and mixtures thereof. Among organocarboxylic adds, preferred are carboxylic adds of formula R¹¹COOH, where R¹¹ is an aliphatic group, an aromatic group, a polyalkoxy group, or a mixture thereof. Among organocarboxylic acids in which R¹¹ is an aliphatic group, preferred aliphatic groups are methyl, propyl, octyl, oleyl, and mixtures thereof. Among organocarboxylic adds in which R¹¹ is an aromatic group, the preferred aromatic group is C₆H₅. Preferably R¹¹ is a polyalkoxy group. When R¹¹ is a polyalkoxy group, R¹¹ is a linear string of alkoxy units, where the alkyl group in each unit may be the same or different from the alkyl groups in other units. Among organocarboxylic acids in which R¹¹ is a polyalkoxy group, preferred alkoxy units are methoxy, ethoxy, and combinations thereof. Functionalized nanoparticles are described, e.g., in US2013/0221279.

Preferably, the amount of functionalized nanoparticles in the formulation (calculated on a solids basis for the entire formulation) is from 50 to 95 wt %; preferably at least 60 wt %, preferably at least 70 wt %, preferably at least 80 wt %, preferably at least 90 wt %; preferably no greater than 90 wt %.

A diazonaphthoquinone inhibitor provides sensitivity to ultraviolet light. After exposure to ultraviolet light, diazonaphthoquinone inhibitor inhibits dissolution of the photoresist film. The diazonaphthoquinone inhibitor may be made from a diazonaphthoquinone having one or more sulfonyl chloride substituent groups and which is allowed to react with an aromatic alcohol species, e.g., cumylphenol, 1,2,3-trihydroxybenzophenone, p-cresol timer or the cresol novolak resin itself.

Preferably, the cresol novolac resin has epoxy functionality from 2 to 10, preferably at least 3; preferably no greater than 8, preferably no greater than 6. Preferably, the cresol novolac resin comprises polymerized units of cresols, formaldehyde and epichlorohydrin.

Preferably, the film thickness is at least 50 nm, preferably at least 100 nm, preferably at least 500 nm, preferably at least 1000 nm; preferably no greater than 3000 nm, preferably no greater than 2000 nm, preferably no greater than 1500 nm. Preferably, the formulation is coated onto standard silicon wafers or Indium-Tin Oxide (ITO) coated glass slides.

### Examples

### 1.1 Materials

Pixelligent PN zirconium oxide (ZrO₂) functionalized nanoparticles with a particle size distribution ranging from 2 to 13 nm were purchased from Pixelligent Inc. These nanoparticles were synthesized via solvo-thermal synthesis, with a zirconium alkoxide based precursor. The potential zirconium alkoxide based precursor used may include zirconium (IV) isopropoxide isopropanol, zirconium (IV) ethoxide, zirconium (IV) n-propoxide, and zirconium (IV) n-butoxide. Different potential capping agents described in the text of this invention can be added to the nanoparticles via a cap exchange process. The positive broadband g-line and i-line capable SPR-220 photoresist was purchased from MicroChem. The developer MF-26A (2.38 wt % tetramethyl ammonium hydroxide) was provided by the Dow Electronic Materials group. The composition of the positive photoresist used, SPR-220 is summarized in Table 1.

TABLE 1
Composition of the positive photoresist SPR-220.

| Component | Percentage |
|---|---|
| Ethyl lactate | 30-50 |
| Anisole | 15-25 |
| Diazo photoactive compound | 1-10 |
| Cresol Novolak resin | 14-40 |
| Cresol | 0.01-0.99 |
| 2-Methyl Butyl Acetate | 1-5 |
| n-amyl acetate | 2-7 |
| Organic Siloxane Surfactant | 0.01-0.1 |

### 1.2 Thin Film Preparation

Solutions were prepared containing different ratios of Pixelligent PA (Pix-PA) and Pixelligent PN (Pix-PB) type nanoparticles (both based on functionalized zirconium oxide nanoparticles) solutions mixed with the positive photoresist SPR-220. The solutions obtained were left to stir overnight and further processed into thin films on ITO coated glass (<15 Ω/sq), as well as silicon wafers via a spin coater with a spin speed of 1500 rpm for 2 min. The weight percentage of nanoparticles in the nanoparticle-photoresist solution was determined via TGA, and the percentages of nanoparticles in the fabricated thin film were then recalculated based on the numbers obtained, and the solids content of the photoresist determined via TGA as well.

### 1.3 Dielectric Strength Measurements

Four 50 nm thick gold electrodes 3 mm in diameter were deposited on the ITO-deposited nanoparticle-photoresist thin film. The breakdown voltage was determined by measuring the current as the voltage applied to the electrodes was increased by 25 V every 5 s up to 1,000 V. The current was recorded every 0.25 s and the last four measurements were averaged to give the current at the desired voltage. The first four seconds of data were discarded due to the presence of a buffer implemented to allow the instrument to survive up to 1,000 V.

### 1.4 Dielectric Constant Characterization

Four 50 nm thick gold electrodes 3 mm in diameter were deposited on the ITO-deposited nanoparticle-photoresist thin films at a rate of 1 Å/s. The ITO was contacted with an alligator clip, and the gold electrodes with a thin gold wire. The capacitance was measured for each sample at 1.15 MHz using a Novocontrol Alpha-A impedance analyzer, and the dielectric constant was determined via Equation 1 with C being the capacitance, Πᵣ the dielectric constant, Π₀ the vacuum dielectric permittivity, A the area of the electrode, and d the thickness of the photoresist. Each film was measured in four different locations to determine a standard deviation.

C=ΠᵣΠ₀·A/d Equation 1

### 1.5 Thickness of the Films

The coatings were scratched with a razor blade using different down forces to make trenches. Profilometry was performed on a DEKTAK 150 stylus profilometer across the trench where the ITO substrate was exposed. Thicknesses were recorded on the flat areas of the profile generated with a scan length of 500 μm, a scan resolution of 0.167 μm per sample, a stylus radius of 2.5 μm, a stylus force of 1 mg, and with the filter cutoff in the OFF mode.

### 1.6 Photoimageability (Flood Exposure)

Photoimageability conditions are summarized in Table 2 as times to achieve less than 10% retained film. The films were subjected to a soft bake at 115° C. for 5 min. They were subsequently exposed to UV radiation via the use of an Oriel Research arc lamp source housing a 1000 W mercury lamp fitted with a dichroic beam turning mirror designed for high reflectance and polarization insensitivity over a 350 to 450 primary spectral range. The developer used was MF-26A based on tetramethyl ammonium hydroxide. After post bake, the coated wafers were dipped into a petri dish containing MF-26A for 6 min. Thickness of the films after each dipping time was determined via an M-2000 Woollam spectroscopic ellipsometer.

TABLE 2
Photoimageability conditions.

| UV Exposure | Hold Time | Post Bake @ 115° C. |
|---|---|---|
| 380 mJ/cm² | 35 min | 2 min |

### 2. Results

### 2.1 Dielectric Constant Results

Table 3 lists the permittivities measured at 1.15 MHz of several thin films made of different amounts of Pixelligent PA (Pix-PA) and Pixelligent PN (Pix-PN) type nanoparticles mixed with the SPR-220 positive photoresist, as a function of weight percent of nanoparticles incorporated in the photoresist. The permittivity obtained for the Pixelligent PA type nanoparticle based thin films was as high as 8.88 for 89.1 wt % of nanoparticles present in the given thin film, while it was as high as 8.46 for the Pixelligent PN type nanoparticle based thin films for 81.23 wt % of nanoparticles present the given thin film. Both results are significantly higher than the permittivity of the base SPR-220 photoresist, as well as the dielectric constant CTQ required by Dow customers.

TABLE 3
Permittivity measured at 1.15 MHz of SPR-220-nanoparticle
thin films, as a function of the weight percent of nanoparticles
incorporated in the photoresist.

| | | | | Wt % of | | |
|---|---|---|---|---|---|---|
| | | | SPR- | nanoparticles | Permit- | Standard |
| Sample | Pix-PA | Pix-PN | 220 | in thin film | tivity | deviation |
| Pix-p-1 | 2.0017 | | 0.2507 | 93.24 | 7.99 | 0.86 |
| Pix-p-2 | 2.0014 | | 0.5012 | 89.16 | 8.80 | 0.98 |
| Pix-p-3 | 1.9999 | | 1.0004 | 79.58 | 7.02 | 0.35 |
| Pix-p-4 | 2.0014 | | 2.0096 | 67.07 | 5.04 | 1.12 |
| Pix-p-5 | 2.0004 | | 3.0003 | 61.78 | 5.46 | 0.24 |
| Pix-p-6 | | 2.0048 | 0.2519 | 92.94 | 4.25 | NA |
| Pix-p-7 | | 2.0058 | 0.5178 | 73.57 | 8.46 | 0.68 |
| Pix-p-8 | | 2.0024 | 1.0494 | 79.46 | 7.15 | 0.15 |
| Pix-p-9 | | 2 | 1.9998 | 62.71 | 4.46 | 1.27 |
| SPR- | | | | | 4.14 | 0.1 |
| 220 | | | | | | |

### 2.2 Photoimageability of the Composite Thin Films

Table 4 shows the thicknesses of the SPR-220-nanoparticle thin films before and after experiencing the exposure conditions detailed in Table 3, and a 6 min soak time in the developer MF-26A (2.38 wt % TMAH). The films containing the Pix PN type nanoparticles were completely removed after 6 min, regardless of the concentration of nanoparticles present in the films In the case of the thin films containing the Pix-PA nanoparticles, only the thin film containing the largest amount of nanoparticles was almost completely removed. This could be assigned to the lower thickness of this film (˜1615 nm) when compared to the thicknesses of the other films containing this type of nanoparticles (>3000 nm). The difference between the removability of the thin films containing Pix PA and Pix PN nanoparticles could be explained by the different ligands attached to both types of nanoparticles, with the ligand attached to the Pix PA type nanoparticles potentially crosslinking more strongly under UV exposure.

TABLE 4
Thickness of the SPR-220 nanoparticle thin films before
and after experiencing exposure and developing conditions.

| | | | | | Thick- | |
|---|---|---|---|---|---|---|
| | | | | | ness | |
| | | | | | before | Thickness |
| | | | | | ex- | after |
| | | | SPR- | Wt % of | posure | 6 min |
| Sample | Pix-PA | Pix-PN | 220 | nanoparticles | (nm) | developer |
| Pix-p-1 | 2.0017 | | 0.2507 | 93.24 | 1615.61 | 34.20 |
| Pix-p-2 | 2.0014 | | 0.5012 | 89.16 | 3196.25 | 2027.80 |
| Pix-p-3 | 1.9999 | | 1.0004 | 79.58 | 4503.38 | 3633.81 |
| Pix-p-4 | 2.0014 | | 2.0096 | 67.07 | 4984.48 | 3754.52 |
| Pix-p-5 | 2.0004 | | 3.0003 | 61.78 | 5912.51 | 1320.59 |
| Pix-p-6 | | 2.0048 | 0.2519 | 92.94 | 190.23 | 3.22 |
| Pix-p- | | 2.0058 | 0.5178 | 73.57 | 2892.15 | 4.26 |
| 7-2 | | | | | | |
| Pix-p-8 | | 2.0024 | 1.0494 | 79.46 | 3964.91 | 2.73 |
| Pix-p-9 | | 2 | 1.9998 | 62.71 | 3157.62 | 8.51 |
| Pix-p- | | 2.0004 | 3.0002 | 62.60 | 3404.53 | 7.21 |
| 10 | | | | | | |

### 2.3 Dielectric Strength of the Thin Films

Table 5 shows the dielectric strength of the thin films produced as a function of the weight percent of nanoparticles in the thin films. Data in the table clearly indicate that a dielectric strength of up to 288 V/μm could be obtained for the composite photoresist-nanoparticle thin films based on Pixelligent PA type nanoparticles. A dielectric strength up to 229 V/μm could be obtained for the thin films based on the Pixelligent PN type nanoparticles. Although the trend was slightly less pronounced in the case of the thin films containing the Pix-PN nanoparticles, the dielectric strength obtained increased as a function of the amount of nanoparticles present in the thin films. The sudden dielectric strength decrease observed for the composite thin films containing 93.24 wt % could be attributed to a higher number of defects in the films (e.g., voids, pores, etc.) due to the very high weight percent of nanoparticles in the film.

TABLE 5
Dielectric strengths of the thin films based on Pix-PA and Pix-PN.

| | | | | | Dielectric | |
|---|---|---|---|---|---|---|
| | Pix-PA | Pix-PN | SPR- | Wt. % of | strength | |
| Sample | (g) | (g) | 220 (g) | nanoparticles | (V/um) | Stdev |
| Pix-p-1 | 2.0017 | | 0.2507 | 93.24 | 143.60 | 15.21 |
| R4 | | | | | | |
| Pix-p-2 | 2.0014 | | 0.5012 | 89.16 | 288.14 | 43.22 |
| R2 | | | | | | |
| Pix-p-3 | 1.9999 | | 1.0004 | 79.58 | 179.94 | 3.68 |
| Pix-p-4 | 2.0014 | | 2.0096 | 67.07 | 153.26 | 2.50 |
| R2 | | | | | | |
| Pix-p-5 | 2.004 | | 3.0003 | 61.78 | 131.15 | 1.89 |
| Pix-p-7 | | 2.0058 | 0.5178 | 73.57 | 229.01 | 16.43 |
| Pix-p-8 | | 2.0024 | 1.0494 | 79.46 | 157.14 | 2.71 |
| R2 | | | | | | |
| Pix-p-9 | | 2 | 1.9998 | 62.71 | 72.30 | 0.92 |
| Pix-p-10 | | 2.004 | 3.0002 | 62.60 | 39.53 | 13.93 |
| SPR-220 | | | | 0 | 26.8 | 0 |

Tables 6 shows the energy storage density of the different thin films produced. The energy storage density of the films was calculated based on the measured dielectric constant and dielectric strength of the different thin films produced via Equation 2. The dielectric constants of the different thin film are represented in Table 3. An energy storage density of up to 3.23 J/cm³ could be obtained for thin films containing the Pixelligent PA type nanoparticles.

Uₘₐₓ=½εε₀E_{b}² Equation 2

TABLE 6
Energy storage density of the thin films based on Pix-PA and Pix-PN.

| | Pix-PA | Pix-PN | SPR- | Wt. % of | Umax | |
|---|---|---|---|---|---|---|
| Sample | (g) | (g) | 220 (g) | nanoparticles | (J/cm³) | Stdev |
| Pix-p-2 | 2.0014 | | 0.5012 | 89.16 | 3.23 | 0.7747 |
| R2 | | | | | | |
| Pix-p-3 | 1.9999 | | 1.0004 | 79.58 | 1.01 | 0.0574 |
| Pix-p-4 | 2.0014 | | 2.0096 | 67.07 | 0.52 | 0.1168 |
| R2 | | | | | | |
| Pix-p-5 | 2.004 | | 3.0003 | 61.78 | 0.42 | 0.0200 |
| Pix-p-7 | | 2.0058 | 0.5178 | 73.57 | 0.78 | 0.0408 |
| Pix-p-8 | | 2.0024 | 1.0494 | 79.46 | 0.10 | 0.0295 |
| R2 | | | | | | |
| Pix-p-10 | | 2.004 | 3.0002 | 62.60 | 1.97 | 0.2537 |
| SPR-220 | | | | 0 | 0.38 | 0.0089 |

1. A formulation for preparing a photo-imageable film; said formulation comprising: (a) a positive photoresist comprising a cresol novolac resin and a diazonaphthoquinone inhibitor; and (b) functionalized zirconium oxide nanoparticles.

2. The formulation of claim 1 in which the functionalized zirconium oxide nanoparticles have an average diameter from 0.3 nm to 50 nm.

3. The formulation of claim 2 in which the functionalized zirconium oxide nanoparticles comprise ligands which have carboxylic acid, alcohol, trichlorosilane, trialkoxysilane or mixed chloro/alkoxy silane functionality.

4. The formulation of claim 3 in which the ligands have from one to twenty non-hydrogen atoms.

5. The formulation of claim 4 in which the cresol novolac resin has epoxy functionality from 2 to 10.

6. The formulation of claim 5 in which the amount of functionalized nanoparticles in the formulation, calculated on a solids basis for the entire formulation, is from 50 to 95 wt %.

7. The formulation of claim 6 in which the cresol novolac resin comprises polymerized units of cresols, formaldehyde and epichlorohydrin.
